(19) United States
(12) Patent Application Publication
(10) Pub. No.: US 2005/0023636 A1
(43) Pub. Date: Feb. 3, 2005

(54) Semiconductor device and method for manufacturing the same

(75) Inventor: Toshihiko Higuchi, Yamanashi-ken (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/928,968

(22) Filed: Aug. 27, 2004

Related U.S. Application Data
(62) Division of application No. 09/910,447, filed on Jul. 19, 2001.

(30) Foreign Application Priority Data
Jul. 19, 2000 (JP) 2000-218890(P)

(51) Int. Cl. H01L 29/76

(52) U.S. Cl. 257/510

(57) ABSTRACT

The invention provides an improved semiconductor and an improved method for manufacturing the device. In a preferred embodiment, a gate electrode is formed on a semiconductor substrate through a gate dielectric layer. First and second impurity diffusion layers are formed in the semiconductor substrate on either side of the gate electrode, with the gate electrode interposed between the first and second impurity diffusion layers. Sidewall dielectric layers are formed on side surfaces of the gate electrode and configured so that the gate electrode has a width that increases gradually from a bottom of the gate electrode toward a top surface of the gate electrode. The first and second impurity diffusion layers are formed thick enough that the surfaces of the first and second impurity diffusion layers are higher than the interface between the semiconductor substrate and the gate dielectric layer. This allows a further miniaturized transistor with favorable transistor characteristics because the film thicknesses of the first and second impurity diffusion layers are maintained.

### BACKGROUND OF THE INVENTION

The invention relates to a semiconductor device and a method for manufacturing the same, and more particularly to a miniaturized semiconductor device and a method for manufacturing the same.

Realization of more miniaturized and faster devices is desired for semiconductor devices including, for example, complementary type MOS semiconductor devices. Gate electrodes for this type of element are required to have a width shorter than a wavelength of light that is used in the photolithography used to manufacture them. Forming such miniaturized gate electrodes requires improved process technology.

With further miniaturization of semiconductor devices, in particular, complementary type MOS semiconductor devices, the resistance of impurity diffusion layers that form sources and drains increases, and wiring delay resulted from the increased resistance of impurity diffusion layers is becoming more apparent. A technology in which a metal silicide layer such as a cobalt silicide layer or a titanium silicide layer is formed in a self-alignment manner over an impurity diffusion layer, namely, a salicide process (SALICIDE: Self-Aligned Silicide), has been developed as a countermeasure to solve the wiring delay. The resistance of the impurity diffusion layer can be lowered by the salicide process.

Increasing miniaturization requires the formation of impurity diffusion layers that are much shallower than before. However, when a formed impurity diffusion layer is so shallow and a silicide layer is formed on the impurity diffusion layer, metal diffuses in the silicon in the silicide. This causes a phenomenon in which electrons of the diffused metal pass through the junction. As a result, a leak current may be generated, which is one of the factors that deteriorate the transistor characteristics of the device. This makes it difficult to develop further miniturized device elements with good transistor characteristics.

The present invention provides a further miniaturized semiconductor device with good transistor characteristics, and a method for manufacturing the same.

### SUMMARY OF THE INVENTION

The invention provides an improved semiconductor and an improved method for manufacturing the device.

In a preferred embodiment, a gate electrode is formed on a semiconductor substrate through a gate dielectric layer. First and second impurity diffusion layers are formed in the semiconductor substrate on either side of the gate electrode, with the gate electrode interposed between the first and second impurity diffusion layers. In a particular preferred embodiment, sidewall dielectric layers are formed on side surfaces of the gate electrode and configured so that the gate electrode has a width that increases gradually from a bottom of the gate electrode toward a top surface of the gate electrode.

This configuration provides a miniaturized gate electrode, in which the resistance of the gate electrode is lowered in comparison with existing gate electrodes, without increasing the gate length.

In particular preferred embodiments, the first and second impurity diffusion layers are formed thick enough that the surfaces of the first and second impurity diffusion layers are higher than the interface between the semiconductor substrate and the gate dielectric layer. This allows a further miniaturized transistor with favorable transistor characteristics because the film thicknesses of the first and second impurity diffusion layers are maintained.

In one particular method for manufacturing the improved semiconductor device, the device is formed by first forming a groove section at a specified location in a semiconductor substrate. The gate electrode will be formed on a bottom surface of this groove section through the gate dielectric layer. This method partially embeds the gate electrode in the semiconductor substrate, so that the apparatus as a whole can be made thinner without having to change the height of the gate electrode.

In preferred embodiments, the gate electrode may be formed from alloys of polycrystalline silicon, tungsten, tantalum, copper and gold.

In some embodiments, an element isolation region is formed in the semiconductor substrate, with the element isolation layer formed with a dielectric layer embedded in a trench isolation groove.

In some preferred embodiments, first and second impurity diffusion layers may include an extension region.

In some embodiments, a third impurity layer is formed in a region immediately below the gate electrode in the semiconductor substrate. In these embodiments, the third impurity diffusion layer functions as a channel region, and its threshold value can be adjusted by selecting the film thickness of the third impurity diffusion layer. In this configuration, moreover, electric fields that might be concentrated at end regions of the diffusion layer are alleviated.

In some embodiments, a metal silicide layer may be formed on the first and second impurity diffusion layers, with a metal silicide layer formed as well on an upper surface of the gate electrode. This structure provides a decreased resistance in the first and second impurity layers and the gate electrode.

In some embodiments, the sidewall dielectric layer is formed from a material including, as a main component, silicon nitride, silicon oxide, or a compound film of these materials.

In some embodiments, surfaces of the first and second impurity layers may preferably be formed at a position above a surface of the element isolation region.

In some embodiments, the sidewall dielectric layer has an outer surface that is generally vertical with respect to the surface of the semiconductor substrate, and a film thickness that gradually decreases from a bottom thereof toward an upper surface thereof This results in a structure that is miniaturized with the resistance of the gate electrode being decreased without elongating the gate length.

A preferred method for manufacturing the semiconductor device includes forming a first dielectric layer on a semiconductor substrate in layers. Parts of the first dielectric layer and the semiconductor substrate are removed to form a groove at a specified position. A sidewall dielectric layer is formed on a side surface section of the groove using a second dielectric layer from a material different from the first dielectric layer. A gate dielectric layer is then formed on a bottom surface of the groove. A conductive material is embedded in the groove and the first dielectric layer is removed to expose a surface of the semiconductor substrate and thereby form a gate electrode. An impurity is introduced in the semiconductor substrate to form first and second impurity diffusion layers with the gate electrode interposed between them.

In embodiments of this type, the gate length of the gate electrode can be controlled by controlling the width of the groove and the film thickness of the sidewall dielectric layer to specified amounts. This allows greater flexibility in designing the device, and a gate electrode having reduced gate length can be provided without using highly advanced process technology.

### BRIEF DESCRIPTION OF THE DRAWINGS

FIG. 1 is a schematic cross-section showing a semiconductor device in accordance with one embodiment of the present invention formed on a semiconductor substrate.

FIG. 2 illustrates the formation of trench isolation grooves in a semiconductor substrate of FIG. 1.

FIG. 3 depicts the formation of a first dielectric layer over the semiconductor substrate and trench isolation grooves of FIGS. 1 and 2.

FIG. 4 shows the formation of a groove at a specified position through the first dielectric layer and partially into the semiconductor substrate of FIGS. 1-3.

FIG. 5 illustrates the deposition of an impurity into the semiconductor substrate at the bottom of the groove of FIG. 4.

FIG. 6 depicts the formation of sidewall dielectric layers on the sides of the groove of FIG. 5.

FIG. 7 illustrates the deposition of a second impurity into the impurity layer of FIG. 5, and the formation of a gate dielectric layer over the second impurity.

FIG. 8 depicts the embedding of an electrical conductor into the groove of FIG. 7.

FIG. 9 illustrates the removal of the first dielectric layer from the semiconductor substrate.

FIG. 10 depicts the formation of impurity diffusion layers on either side of a gate electrode on the semiconductor surface.

### DETAILED DESCRIPTION OF THE PREFERRED EMBODIMENTS

Preferred embodiments of the present invention are described below with reference to the accompanying drawings.

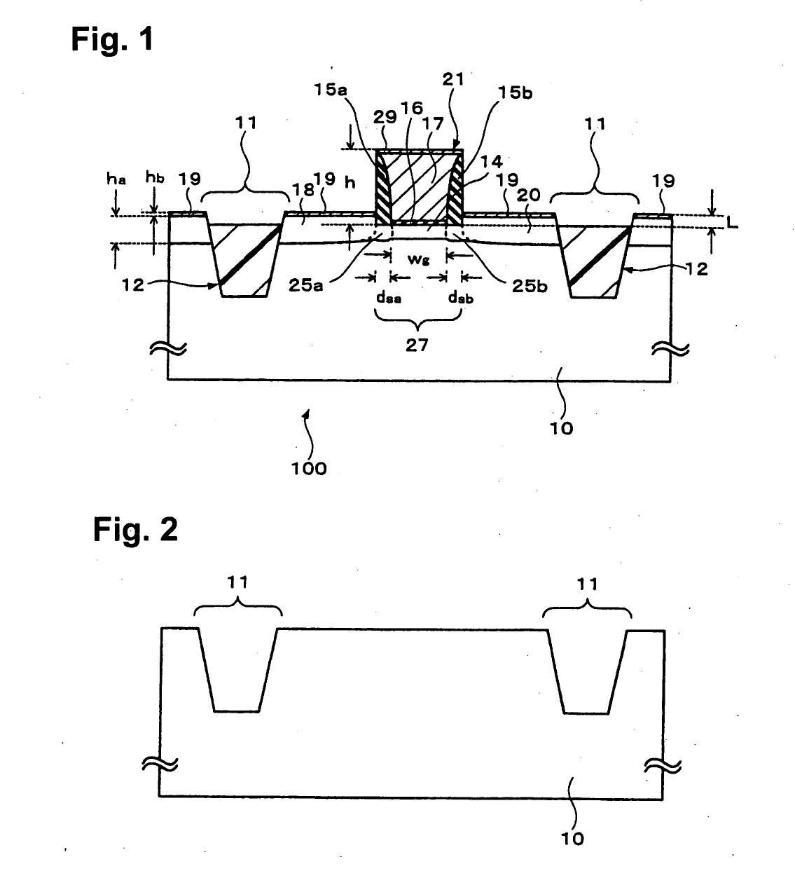

First, a method for manufacturing a semiconductor device 100 in accordance with a first embodiment of the present invention is described with reference to FIGS. 2-10. FIGS. 2-10 are cross-sectional views that depict schematically manufacturing processes for producing the semiconductor device 100 shown in FIG. 1.

The method for manufacturing the semiconductor device 100 in accordance with the present embodiment mainly includes steps (a)-(f), as described below.

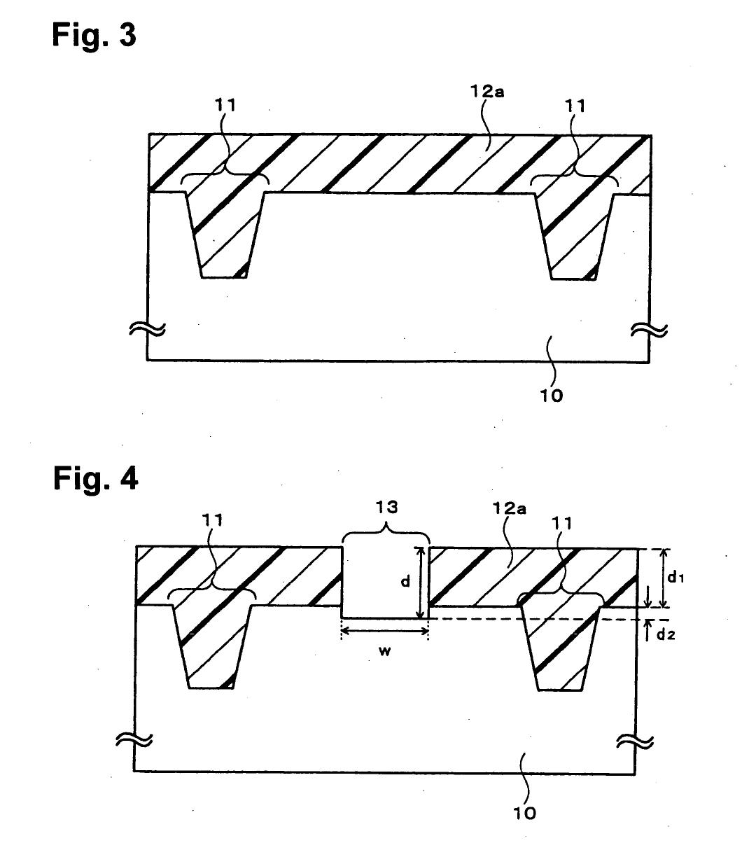

In step (a), a first dielectric layer 12a (see FIG. 3) is formed on a silicon semiconductor substrate 10.

In step (b), a part of the first dielectric layer 12a and the silicon substrate 10 are removed (see FIG. 4) to form a groove 13 at a specified position.

In step (c), sidewall dielectric layers 15a, 15b (see FIG. 6) are formed on a side surface section of the groove 13 using a second dielectric layer (not shown) that is composed of a material different from the first dielectric layer 12a.

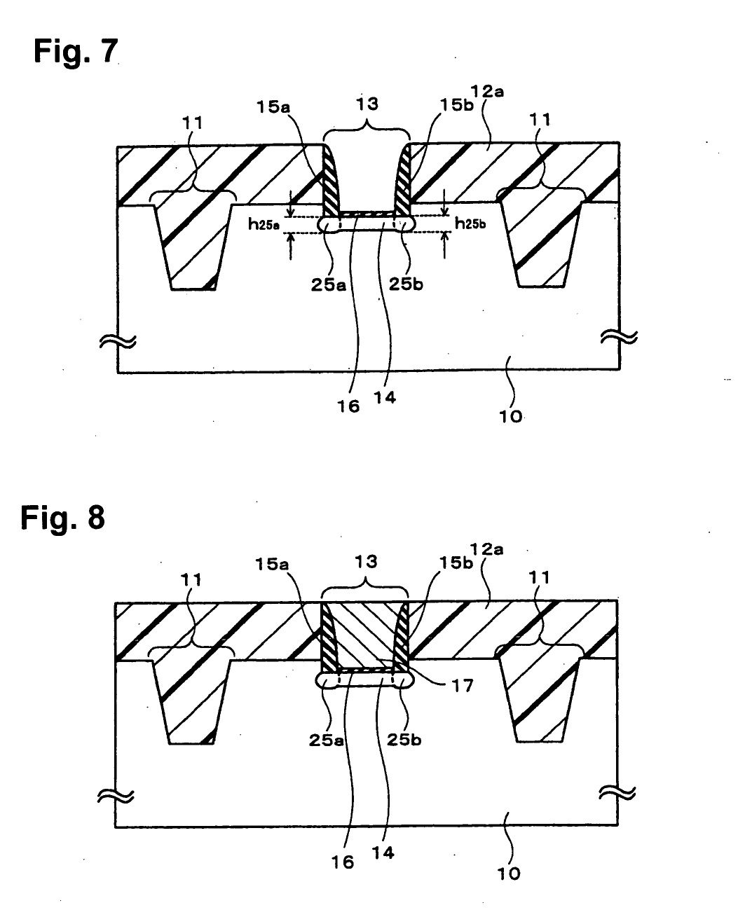

In step (d), a gate dielectric layer 16 (see FIG. 7) is formed on a bottom surface of the groove 13.

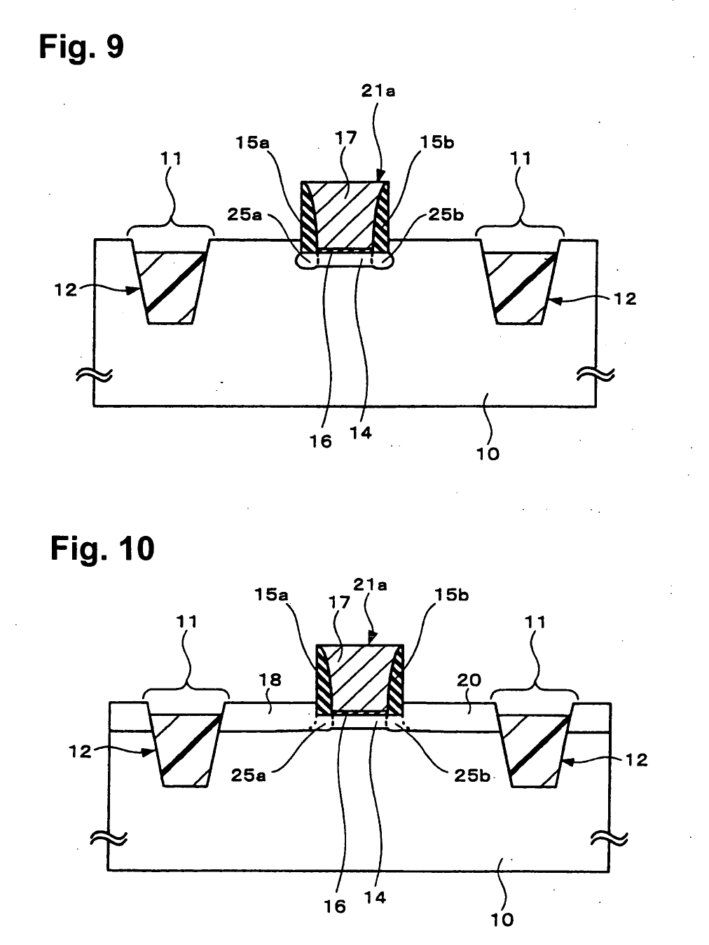

In step (e), a conductive material 17 is embedded in the groove 13, and then the first dielectric layer 12a is removed until at least a surface of the silicon substrate 10 is exposed (see FIG. 9) to thereby form a gate electrode 21.

In step (f), an impurity is introduced in the silicon substrate 10 to thereby form a first impurity diffusion layer 18 (see FIG. 10) and a second impurity diffusion layer 20 in the silicon substrate 10 with the gate electrode 21 interposed therebetween.

By the steps described above, the semiconductor device 100 shown in FIG. 1 is obtained. The semiconductor device 100 includes a gate electrode 21 and with a configuration in which the width of the gate electrode 21 gradually increases from its bottom surface toward its top surface.

Step (a) is described below.

First, as shown in FIG. 2, trench isolation grooves 11 are formed to form an element isolation region. More specifically, a resist (not shown) having a predetermined pattern is formed on the silicon substrate 10 of a second conduction type (P type), and then the silicon substrate 10 is etched to form the trench isolation grooves 11 shown in FIG. 2. Then, a non-doped silicon oxide layer is formed by a CVD method or a plasma CVD method. The forming method that is generally practiced to form a non-doped silicon oxide layer includes a CVD method by a pyrolysis using a reactant gas such as O₃, TEOS (tetraethylorthosilicate), or a silane gas other than TEOS, or a plasma CVD method such as an HDP (High Density Plasma) CVD method. As shown in FIG. 3, the trench isolation grooves 11 are embedded with the first dielectric layer 12a, as the first dielectric layer 12a having a specified film thickness is deposited on the silicon substrate 10 in layers. In the present embodiment, the first conduction type is N-type, and the second conduction type is P-type.

In a preferred embodiment the element isolation region 12 is formed by an STI (Shallow Trench Isolation) method. However, the method of forming the element isolation region is not limited to this embodiment. The element isolation region can be provided by a LOCOS method, for example. Moreover, a non-doped silicon oxide layer may be used as the first dielectric layer 12a.

After the grooves 11 are formed and the first dielectric layer 12a is deposited, the surface of the first dielectric layer is planarized by CMP (Chemical Mechanical Polishing).

Next, a resist (not shown) having a predetermined pattern is formed on the first dielectric layer 12a, and then a part of the first dielectric layer 12a and the silicon substrate 10 is removed by a dry etching method to thereby form a groove 13 as shown in FIG. 4. The groove 13 may preferably be formed such that the width w of the groove 13 (see FIG. 4) will be the sum of a gate length W_{g} (see FIG. 1) of the gate electrode 21 to be formed in later steps and the thicknesses dₛₐ and d_{sb} (see FIG. 1) of the sidewall dielectric layers 15a and 15b. The height of the gate electrode 21 is determined by the depth d of the groove 13 (see FIG. 4). Therefore, in order to obtain a gate electrode 21 having a height h (see FIG. 1), the groove 13 may preferably be formed in a manner that the depth d of the groove 13 is generally equivalent to the required height h of the gate electrode 21. The depth d of the groove 13, as shown in FIG. 4, is the sum of the film thickness d₁ of the first dielectric layer 12a and the depth d₂ of the silicon substrate 10 to be removed (see FIG. 4). Therefore, the film thickness d₁ of the first dielectric layer 12a and the depth d₂ of the silicon substrate 10 to be removed together determine the height h of the gate electrode 21. The depth d₂ of the silicon substrate 10 to be removed may preferably be between about 0.05 and 0.1 μm.

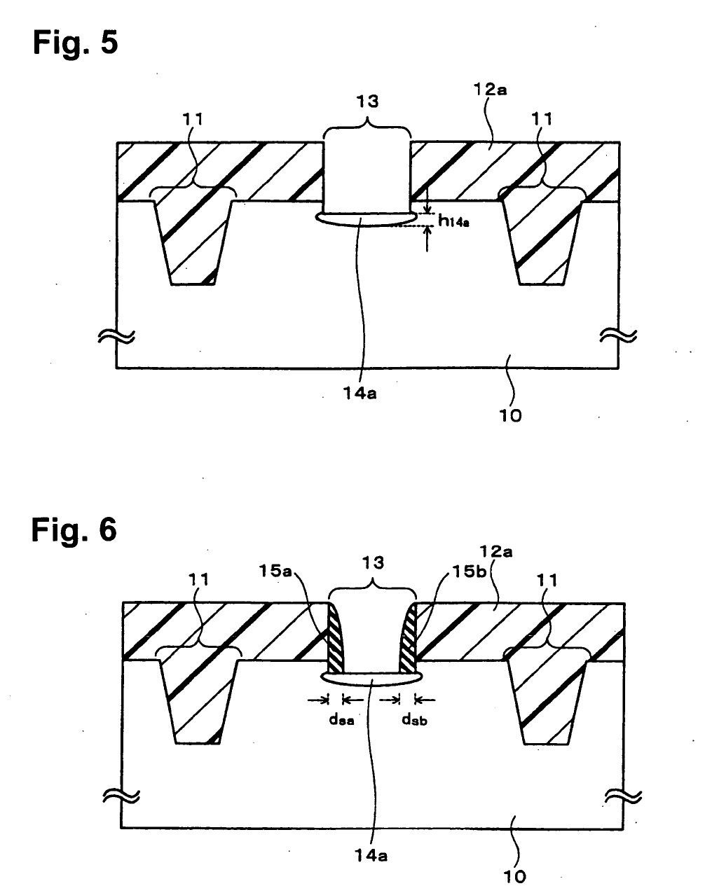

Depending on the requirements, an impurity is introduced in a portion corresponding to the bottom surface of the groove 13 in the silicon substrate 10. By this step, a fourth impurity diffusion layer 14a of a first conduction type (N type) is formed in the bottom surface of the groove 13, as shown in FIG. 5. In this step, an impurity having a conduction type opposite to that of the silicon substrate 10 is introduced into the substrate. According to this process, by forming the fourth impurity diffusion layer 14a, an impurity diffusion layer (an extension region) in which current readily flows is formed in a region adjacent to the gate dielectric layer 16 in the silicon substrate 10 (see FIG. 1). The impurity concentration of the fourth interlayer dielectric layer 14a may preferably be about 1×10¹⁷-10²² cm⁻³. Also, the depth h₁₄ₐ of the fourth impurity diffusion layer 14a (see FIG. 5) may preferably be from about 0.02 μm to about 0.15 μm.

A second dielectric layer (not shown) is deposited on the entire surface of the silicon substrate 10 by a CVD (chemical vapor deposition), and then an anisotropic etching back is conducted to form sidewall dielectric layers 15a, 15b composed of the second dielectric layer, as shown in FIG. 6. The sidewall dielectric layers 15a, 15b each have an outer surface that is generally vertical with respect to the surface of the silicon substrate 10, and a thickness that gradually becomes smaller from a bottom surface thereof toward an upper surface thereof. In other words, the sidewall dielectric layer 15a, 15b has a configuration in which the film thickness thereof becomes smaller as the distance from the bottom surface of the groove 13 becomes greater. Here, the outer surface of the sidewall dielectric layer 15a, 15b means a surface on the opposite side of the surface of the sidewall dielectric layer 15a, 15b that is in contact with the gate electrode 21. By controlling the film thickness of the second dielectric layer to be deposited, the film thickness dₛₐ, d_{sb} of the sidewall dielectric layer 15a, 15_{b} can be controlled. Also, by appropriately controlling the conditions of the CVD, the film thickness dₛₐ, d_{sb} of the sidewall dielectric layer 15a, 15b can be controlled. The sidewall dielectric layer 15a, 15b may preferably be formed from a material that includes, as a main component, silicon nitride, silicon oxide, or a compound film of these materials.

An impurity is introduced in the bottom surface of the groove 13. More specifically, an impurity is introduced with respect to the fourth impurity diffusion layer 14a, and as shown in FIG. 7, a third impurity diffusion layer 14 of a second conduction type (P-type) is formed and extension regions 25a, 25b are formed at both end sections of the third impurity diffusion layer 14. The impurity that is introduced in this step has the same conduction type as that of the silicon substrate 10. The concentration of the impurity to be introduced in this step may preferably be about 1×10¹⁶ cm⁻³-1×10¹⁸ cm⁻³. The film thickness h₂₅ₐ, h_{25b} of the extension region 25a, 25b (see FIG. 7) may preferably be from about 0.05-0.20 μm. A portion located at the bottom surface of the groove 13 in the silicon substrate 10 is thermally oxidized to form a gate dielectric layer 16 composed of a silicon oxide layer.

In the process described above, instead of thermally oxidizing the region at the bottom surface of the groove 13, that region may be nitrified and oxidized using gas containing nitrogen to form a gate dielectric layer 16 composed of a silicon nitride oxide layer (SiON). By forming the gate dielectric layer 16 from silicon nitride oxide layer, the reliability of the gate dielectric layer 16 can be further improved. The gas that is used for the nitrification and oxidization may include, for example, N₂, N₂O, NO, NH₃ and the like. Alternatively, instead of forming the gate dielectric layer 16 by the nitrification and oxidization to form a silicon nitride oxide layer (SiON), the gate dielectric layer 16 can be formed of tantalum oxide or actinium oxide.

As illustrated in FIG. 8, a conduction material 17 is embedded in the groove 13 by conducting a CVD or the like. An alloy containing polysilicon (polycrystalline silicon) or silicon as a main component, or a metal such as tungsten, tantalum, copper, gold can be used as the conduction material. Alternatively, a nitride (barrier layer) of a high melting-point metal such as titanium, tantalum or tungsten stacked in layer with the metal described above can be embedded in the groove 13.

As depicted in FIG. 9, the first dielectric layer 12a and the conduction material are removed at least until the surface of the silicon substrate 10 is exposed. This may be done, e.g., by conducting a CMP method or a CMP method with an etching. This process forms a gate electrode 21a. The gate electrode includes the gate dielectric layer 16 and a conduction layer 17. The conduction layer is formed from a conduction material such as polysilicon or the like formed on the gate dielectric layer 16. Embedded element isolation regions 12 are also formed in the substrate 10.

In the process described above, when silicon nitride is used for the sidewall dielectric layer 15a, 15b, polysilicon is used as a conduction material for forming the conduction layer 17 and silicon oxide is used for the first dielectric layer 12a, and they are subject to the etching described above, the first dielectric layer 12a composed of silicon oxide can be selectively removed because the etching rate of the silicon oxide is substantially different from the etching rate of the silicon nitride and the polysilicon. As a result, the first dielectric layer 12a can be selectively etched back while the shapes of the conduction layer 17 and the sidewall dielectric layers 15a, 15b are maintained

The first dielectric layer 12a that is embedded in the trench isolation grooves 11 may preferably be over-etched by a specified depth from the surface of the silicon substrate 10.

An impurity is introduced in the silicon substrate 10 to form a first impurity diffusion layer 18 and a second impurity diffusion layer 20 of a first conduction type (N-type), as illustrated in FIG. 10. The first and second impurity diffusion layers are opposed to each other with the gate electrode 21a interposed between them in the silicon substrate 10. The first impurity diffusion layer 18 and the second impurity diffusion layer 20 are source/drain regions, and the impurity is introduced so that the impurity concentration of these layers is higher than the impurity concentration of the extension regions 25a, 25b.

Alternatively, an impurity may be introduced so that the impurity concentration of the first impurity diffusion layer 18 and the second impurity diffusion layer 20 is generally the same as the impurity concentration of the third impurity diffusion layer 14. In this process, the impurity is directly introduced in the silicon substrate 10. As a result, a problem in which the impurity adheres around the gate electrode 21a does not occur. Therefore, the introduction of the impurity in this process does not lower the transistor characteristic.

Next, depending on the requirements, the first impurity diffusion layer 18 and the second impurity diffusion layer 20 are activated. Furthermore, depending on the requirements, a metal silicide layer 19 is formed on the silicon substrate 10 using an ordinary salicide process. When the conduction layer 17 is formed from polysilicon, a metal silicide layer 29 is formed on the surface of the gate electrode 21. The metal that forms the metal silicide layer 19 may include, for example, cobalt or titanium. As a result, the metal silicide layer 19 is formed on the silicon substrate 10, and the metal silicide layer 29 is formed on the upper surface of the conduction layer 17. By the process described above, a semiconductor device 100 (see FIG. 1) having the gate electrode 21 that includes the conduction layer 17 and the metal silicide layer 29 is obtained.

The structure of the semiconductor device 100 in accordance with the present embodiment obtained by the process described above is described below. FIG. 1 is cross-sectional schematic of the semiconductor device 100 according to the present embodiment.

As shown in FIG. 1, the semiconductor device 100 includes a silicon substrate 10, a gate electrode 21 formed on the silicon substrate 10 through a gate dielectric layer 16, and a first impurity diffusion layer 18 and a second impurity diffusion layer 20 formed in the silicon substrate 10 and opposed to each other with the gate electrode 21 interposed between them.

The gate electrode 21 includes the conduction layer 17 that is formed on the surface of the silicon substrate 10 and the metal silicide layer 29.

The conduction layer 17 is formed from a conductive material such as polysilicon, as described above.

The gate electrode 21 has a configuration in which its width gradually becomes greater from a bottom surface thereof toward an upper surface thereof. In other words, the gate electrode 21 has a configuration in which, when it is cut in planes in parallel with the surface of the silicon substrate 10, its cross-sectional areas gradually become greater as the distance from the surface of the silicon substrate 10 becomes greater.

Sidewall dielectric layers 15a, 15b are formed on sidewall sections of the gate electrode 21. The sidewall dielectric layers 15a, 15b are formed in a manner that each of them has an outer surface that is generally vertical with respect to the surface of the silicon substrate 10, and a thickness that gradually becomes smaller from a bottom surface thereof toward an upper surface thereof. In other words, the film thickness of the sidewall dielectric layer 15a, 15b becomes smaller as the distance from the surface of the silicon substrate 10 becomes greater. The sidewall dielectric layer 15a, 15b may preferably be formed from a material containing, for example, silicon nitride as a main component.

In the semiconductor device 100, as shown in FIG. 1, the gate electrode 21 is formed on a bottom surface of a groove 27 formed at a predetermined position in the silicon substrate 10 through the gate dielectric layer 16. Therefore, the interface between the silicon substrate 10 and the gate dielectric layer 16 is provided at a location lower than the surface of the first impurity diffusion layer 18 and the second impurity diffusion layer 20. The distance L (see FIG. 1) between the surface of the first impurity diffusion layer 18 and the second impurity diffusion layer 20 and an interface between the silicon substrate 10 and the gate dielectric layer 16 may preferably be from about 0.05 μm to about 0.15 μm. The distance L is determined by the thickness of the silicide layer 19 and the first and second impurity diffusion layers 18 and 20, in particular the thickness of the first and second impurity diffusion layers 18 and 20.

The first impurity diffusion layer 18 and the second impurity diffusion layer 20 of a first conduction type (N-type) are formed on either side of the gate electrode 21 in the silicon substrate 10, interposing the gate electrode 21 between them. The film thickness ha of the first impurity diffusion layer 18 and the second impurity diffusion layer 20 may preferably be between about 0.05 μm and 0.1 μm. A third impurity diffusion layer 14 of a second conduction type (P-type) is formed immediately below the gate electrode 21, being interposed between the first impurity diffusion layer 18 and the second impurity diffusion layer 20. The third impurity diffusion layer 14 is a channel region and is set at a lower impurity concentration compared to that of the first impurity diffusion layer 18 and the second impurity diffusion layer 20, or has an impurity concentration that is generally the same as that of the first impurity diffusion layer 18 and the second impurity diffusion layer 20. By forming extension regions 25a and 25b, electric fields that may concentrate at end sections of the first impurity diffusion layer 18 and the second impurity diffusion layer 20 can be alleviated.

Furthermore, the first impurity diffusion layer 18 and the second impurity diffusion layer 20 have the extension regions 25a and 25b of the same conduction type as that of the first impurity diffusion layer 18 and the second impurity diffusion layer 20 (the first conduction type; N-type) adjacent to a boundary of the third impurity diffusion layer 14. The impurity concentration of the extension regions 25a and 25b have a lower impurity concentration compared to that of the first impurity diffusion layer 18 and the second impurity diffusion layer 20, in a similar manner as the impurity concentration of the third impurity diffusion layer 14, or an impurity concentration that is generally the same as that of the first impurity diffusion layer 18 and the second impurity diffusion layer 20. The extension regions 25a and 25b may preferably have a film thickness of between about 0.05 μm and about 0.10 μm.

An element isolation region 12 is embedded in the silicon substrate 10. The element isolation region 12 is formed by embedding a dielectric layer, such as a silicon oxide layer in a trench isolation groove 11. Moreover, the element isolation region 12 is formed below the surface of the first impurity diffusion layer 18 and the second impurity diffusion layer 20.

Furthermore, a metal silicide layer 19 is formed on the silicon substrate 10. The film thickness h_{b} of the metal silicide layer 19 may preferably be between about 0.03 and 0.10 μm. When the conduction layer 17 is formed from polysilicon, the gate electrode 21 includes a metal silicide layer 29 on its surface.

Actions and effects in the semiconductor device in accordance with the present embodiment and the corresponding manufacturing method are described below.

The gate electrode 21 has a configuration in which its width gradually becomes greater from a bottom surface thereof toward an upper surface thereof. In contrast, a gate electrode that is formed in an ordinary semiconductor device has a width that is generally the same at its upper surface and its bottom surface. Therefore, when the semiconductor device 100 in accordance with the present embodiment and an ordinary semiconductor device in which its gate width is generally the same at its upper surface and its bottom surface include gate electrodes having generally the same gate length, the gate electrode 21 formed in the semiconductor device 100 of the present embodiment has a greater volume because the width of the gate electrode 21 gradually becomes greater from its bottom surface toward its upper surface. As a result, a further miniaturization is attained and a lower resistance is achieved without increasing the gate length.

In the manufacturing process in accordance with the present embodiment, the groove 13 and the sidewall dielectric layers 15a, 15b are formed so that the width w of the groove 13 (see FIG. 4) that is used for forming the gate electrode 21 and the film thickness dₛₐ, d_{sb} of the sidewall dielectric layer. 15a, 15b (see FIG. 6) have specified values, whereby the gate electrode 21 having a desired gate length w_{g} (see FIG. 1) can be obtained. In other words, by appropriately adjusting the width w of the groove 13 and the film thicknesses dₛₐ, d_{sb} of the sidewall dielectric layer 15a, 15b, the gate electrode 21 having a desired gate length w_{g} (see FIG. 1) can be obtained. Here, the width w of the groove 13 can be readily controlled to a specified value by the size of the resist formed for photolithography.

It should be noted that, with further miniaturization of semiconductor devices being in progress, the gate length of gate electrodes is further miniaturized. In particular, in recent years, gate electrodes having a gate length shorter than a wavelength of light have been required. However, in many cases, it is technically difficult to accurately process gate electrodes having such a short gate length. Also, as the gate length of gate electrodes becomes shorter, the process for forming gate electrodes and other manufacturing processes relating thereto may have to be substantially changed in many occasions. Therefore, it takes a long time to develop a semiconductor device having a gate electrode of a much shorter gate length.

In contrast, by the manufacturing process in accordance with the present embodiment, by appropriately adjusting the film thickness dₛₐ, d_{sb} of the sidewall dielectric layer 15a, 15b, a gate electrode having a shorter gate length can readily be obtained. Also, the process for forming gate electrodes and other manufacturing processes relating thereto do not have to be changed to form a shorter gate length, the time required for development of a semiconductor device can be shortened.

Also, when the sidewall dielectric layers 15a and 15b are formed by employing CVD, the type of gas to be used and conditions of the CVD, such as processing time, may be appropriately controlled, with the result that the film thickness dₛₐ, d_{sb} of the sidewall dielectric layer 15a, 15b can be readily controlled. Therefore, by the process described above, the degree of freedom in design can be increased. In addition, without using a highly advanced process technology, a gate electrode having a much finer gate length can be obtained.

Furthermore, by using the process for manufacturing semiconductor devices in accordance with the present embodiment, the width w of the groove 13, and the film thickness dₛₐ, d_{sb} of the sidewall dielectric layer 15a, 15b, for each of the elements may be set to any specified values. As a result, the elements in plurality having different gate lengths can be obtained in the same process. Accordingly, the time for the manufacturing process is shortened, and as a result, the manufacturing cost is reduced.

The first impurity diffusion layer 18 and the second impurity diffusion layer 20 can be formed thicker by an amount in which the surfaces of the first impurity diffusion layer 18 and the second impurity diffusion layer 20 are formed at a position higher than the interface between the silicon substrate 10 and the gate dielectric layer 16. As a result, a phenomenon in which electrons in the silicide pass through (i.e., junction leak) can be prevented. As a result, even when a transistor is further miniaturized, the film thickness of the first impurity diffusion layer 18 and the second impurity diffusion layer 20 can be retained, and therefore the transistor characteristic can be maintained.

The interface between the silicon substrate 10 and the gate dielectric layer 16 is provided at a location lower than the surface of the first impurity diffusion layer 18 and the second impurity diffusion layer 20. This results in a structure in which a part of the gate electrode 21 is embedded in the silicon substrate 10. As a result, in the semiconductor device 100, the thickness of the silicon substrate 10 in a stacking direction of the layers can be made thinner without changing the height of the gate electrode 21.

The gate electrode 21 includes a metal silicide layer 29 on its upper surface. As described above, the metal silicide layer 29 is generally formed from a silicide of silicon and titanium or cobalt. In general, when the gate length becomes shorter, the fine-line effect of titanium and cobalt would likely occur, and line breakage would likely occur. However, the gate electrode 21 formed in the semiconductor device 100 of the present embodiment has a configuration in which its shape gradually becomes greater from its bottom surface toward its upper surface. In other words, the gate electrode 21 has a surface area at the bottom surface greater than the surface area at the upper surface thereof Therefore, compared to an ordinary semiconductor device having a gate electrode in which a surface area at its bottom surface is generally the same as a surface area at its upper surface, the fine-line effect would be unlikely to occur in the metal silicide layer 29 that is formed on the upper surface. Therefore, occurrence of line breakage can be prevented, and a highly reliable semiconductor device can be obtained.

In the embodiment described above, the first conduction type is described as being N-type, and the second conduction type is described as being P-type. However, they can be switched with each other for each semiconductor layer without departing from the subject matter of the present invention. In other words, the actions and effects of the present invention can be attained even when the first conduction layer is P-type and the second conduction type is N-type.

1-12. (canceled)

13. A method for manufacturing a semiconductor device, the method comprising the steps of:
forming a first dielectric layer on a semiconductor substrate;
removing a part of the first dielectric layer and the semiconductor substrate to thereby form a groove at a specified position;
forming a sidewall dielectric layer on a side surface section of the groove using a second dielectric layer composed of a material different from the first dielectric layer;
forming a gate dielectric layer on a bottom surface of the groove;
embedding a conductive material into the groove and then removing the first dielectric layer until at least a surface of the semiconductor substrate is exposed to thereby form a gate electrode; and
introducing an impurity in the semiconductor substrate to thereby form first and second impurity diffusion layers in the semiconductor substrate with the gate electrode interposed between them.

14. A method for manufacturing a semiconductor device according to claim 13, wherein the groove and the sidewall dielectric layer are formed to have a specified width and a specified film thickness, respectively, to form a width of the gate electrode to have a specified length.

15. A method for manufacturing a semiconductor device according to claim 13, and further comprising:
forming an element isolation region at a specified location in the semiconductor substrate.

16. A method for manufacturing a semiconductor device according to claim 15, and:
wherein forming the element isolation region includes forming a trench isolation groove at a specified location on the semiconductor substrate before the first dielectric layer is formed;
wherein forming the first dielectric layer on the semiconductor substrate includes embedding the first dielectric layer in the trench isolation groove; and
wherein removing the first dielectric layer includes etching the first dielectric layer to thereby form an element isolation region embedded in the semiconductor substrate.

17. A method for manufacturing a semiconductor device according to any one of claim 13, and further comprising:
introducing an impurity into a region at a bottom surface of the groove in the semiconductor substrate to form a third impurity diffusion layer.

18. A method for manufacturing a semiconductor device according to claim 17, wherein introducing the impurity into the region at the bottom surface of the groove includes introducing an impurity of a first conduction type to form the third impurity diffusion layer; and further comprising:
introducing an impurity of a second conduction type into the third impurity diffusion layer formed of the impurity of the first conduction type to form a fourth impurity diffusion layer.

19. A method for manufacturing a semiconductor device according to claim 13, and further comprising:
forming a metal silicide layer on the first and second impurity diffusion layers, and forming a metal silicide layer on a top surface of the gate electrode.

20. A method for manufacturing a semiconductor device according to claim 13, wherein forming a sidewall dielectric layer on a side surface section of the groove includes:
forming a second dielectric layer over the surface of the semiconductor substrate; and
forming the side wall dielectric layer by anisotropically etching back the second dielectric layer,
wherein the second dielectric layer is formed of a material having an etching rate different from the etching rate of the first dielectric layer.
